(19) United States
(12) Patent Application Publication
(10) Pub. No.: US 2013/0141345 A1
(43) Pub. Date: Jun. 6, 2013

(54) REWORKABLE ELECTRONIC APPARATUS AND THERMAL DISASSEMBLING METHOD THEREOF

(71) Applicant: Ching-Cheng WANG, Dasi Township (TW)

(72) Inventor: Ching-Cheng WANG, Dasi Township (TW)

(73) Assignee: Quanta Computer Inc., Taoyuan Shien (TW)

(21) Appl. No.: 13/461,285

(22) Filed: May 1, 2012

(30) Foreign Application Priority Data
Dec. 6, 2011 (TW) 100144885

(51) Int. Cl. G06F 3/041; H05K 13/00

(52) U.S. Cl. 345/173; 29/592.1

(57) ABSTRACT

A reworkable electronic apparatus is provided, which includes a display module, a frame, an adhesive for adhering the display module to the frame, and at least one shape memory metal piece. The shape memory metal piece is disposed between the display module and the frame. The shape memory metal piece is deformable by heat to lift the display module away from the frame. A thermal disassembling method for the reworkable electronic apparatus is also provided.

### RELATED APPLICATIONS

This application claims priority to Taiwan Application Serial Number 100144885, filed Dec. 6, 2011, which is herein incorporated by reference.

### BACKGROUND

1. Field of Invention

The present invention relates to an electronic apparatus. More particularly, the present invention relates to a reworkable electronic apparatus.

2. Description of Related Art

Along with the development of 3C (Computer, Communications and Consumer) industries, more and more people are using mobile devices as an assistance tool in their daily life. Common mobile devices include personal digital assistants (PDAs), mobile phones, smart phones and so on. These mobile devices are small in size and easy to be carried, and as a result, the number of people using mobile devices is increasing, so is the number of functions required on the mobile devices.

The recent development trend of the mobile devices is towards being lighter and thinner. Not only is the thickness of the mobile devices getting thinner and thinner, but also the width of the mobile devices is getting smaller and smaller, and even a frameless design is utilized in some mobile devices. Therefore, using a display module as an example, it is difficult to fasten the display module on the frame with an engagement mechanism because of the space limitation, and the display module is often mounted on the frame by a backing adhesive. However, the backing adhesive is not friendly to reworking due to difficult to be disassembled, and the glass substrate of the display module may be damaged by improper force application during a rework process, thus increasing the material cost and reducing the product yield.

### SUMMARY

The present invention provides a reworkable electronic apparatus for being easily disassembled.

An aspect of the invention is to provide a reworkable electronic apparatus, which includes a display module, a frame, an adhesive for adhering the display module to the frame, and at least one shape memory metal piece disposed between the display module and frame. The shape memory metal piece is deformable by heat for lifting the display module away from the frame. The shape memory metal piece has a flat surface at a room temperature. The shape memory metal piece can be protruded toward the display module after being heated. The shape memory metal piece can be protruded toward the frame after being heated. The display module includes a display panel, and a touch panel placed on the display panel. The touch panel includes a display area corresponding to the display panel, and a backing adhesive area surrounding the display area. The adhesive is disposed on the backing adhesive area. The frame includes a cavity facing the backing adhesive area for receiving the shape memory metal piece.

Another aspect of the invention is to provide a thermal disassembling method for a reworkable electronic apparatus. The method includes providing the reworkable electronic apparatus, and heating the reworkable electronic apparatus for deforming the shape memory metal piece. Thereby, the display module is lifted away from the frame. The display module can be a display module, and the frame can be a frame. The shape memory metal piece can be protruded toward the display module after being heated. The shape memory metal piece can be protruded toward the frame after being heated.

When the reworkable electronic apparatus is heated to a predetermined temperature, the shape memory metal piece between the display module and the frame is deformed for providing a lifting force. Furthermore, the adhesiveness of the adhesive is reduced because of the raising temperature. Thus, the display module can be easily lifted away from the frame during a rework process, thereby reducing the damage due to forcing disassembly.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional diagram of a reworkable electronic apparatus according to an embodiment of the invention;

FIG. 2A to FIG. 2C are top views the reworkable electronic apparatuses according to different embodiments of the invention;

FIG. 3 is an assembly schematic diagram of the reworkable electronic apparatus according to another embodiment of the invention;

FIG. 4A is a schematic partial diagram of the reworkable electronic apparatus of FIG. 3 before being heated; and

FIG. 4B is a schematic partial diagram of the reworkable electronic apparatus of FIG. 3 after being heated.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

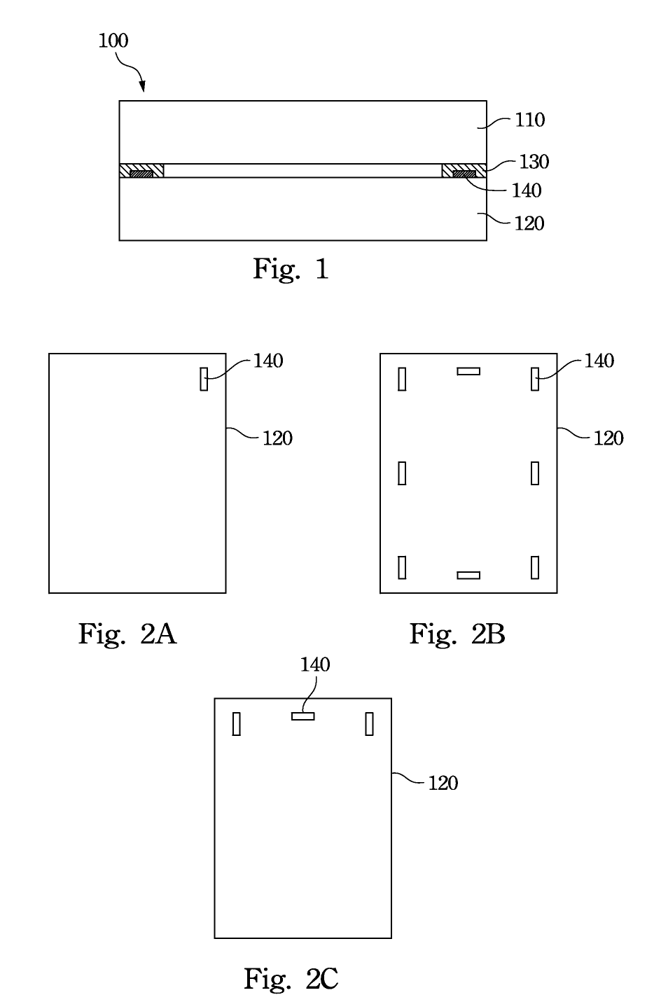

FIG. 1 is a cross-sectional diagram of a reworkable electronic apparatus 100 according to an embodiment of the invention. The reworkable electronic apparatus 100 includes a first component 110, a second component 120, and an adhesive 130. The first component 110 is adhered on the second component 120 with the adhesive 130. The reworkable electronic apparatus 100 includes at least one shape memory metal piece 140. The shape memory metal piece 140 is disposed between the first component 110 and the second component 120. The shape memory metal piece 140 has a characteristic of being deformed under a predetermined temperature, and such a characteristic is utilized in the present invention. The shape memory metal piece 140 having a flat surface under a room temperature is placed between the first component 110 and the second component 120. The shape memory metal piece 140 is deformed when the shape memory metal piece 140 is heated to a predetermined temperature, for example 60° C. The deformation of the shape memory metal piece 140 can lift the first component 110 away from the second component 120.

FIG. 2A to FIG. 2C are top views of the reworkable electronic apparatuses according to different embodiments of the invention. The number of the at least one shape memory metal piece 140 (i.e. Shape Memory Alloys, SMA) can be single, as shown in FIG. 2A. The shape memory metal piece 140 can be disposed on the second component 120 (or the first component 110), in which the shape memory metal piece 140 is placed on an edge of the second component 120. The number of the at least one shape memory metal piece 140 can be plural, as shown in FIG. 2B and FIG. 2C. The shape memory metal pieces 140 can be evenly disposed on the second component 120 (or the first component 110), as shown in FIG. 2B. The shape memory metal pieces 140 can be disposed on one side of the second component 120 (or the first component 110), as shown in FIG. 2C. The shape memory metal piece 140 can be made of iron-based alloy, copper-based alloy, or nickel titanium alloy.

The deformation temperature of the shape memory metal piece 140 can be adjusted by an alloy formula.

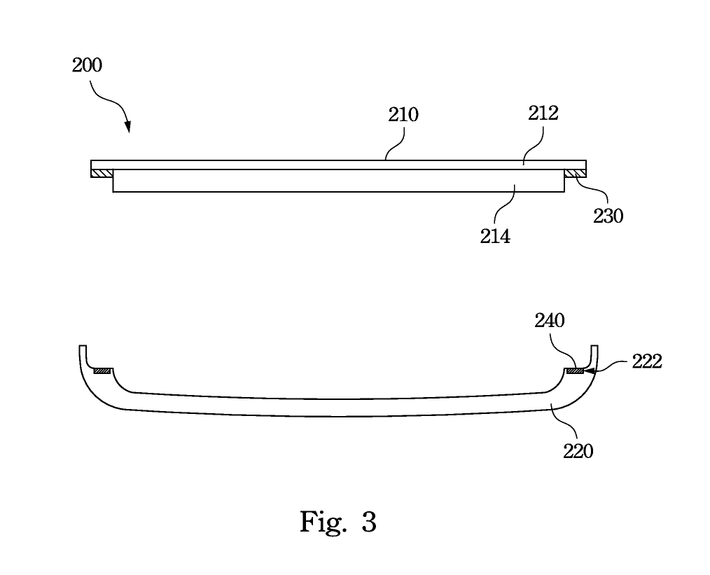

FIG. 3 is an assembly schematic diagram of the reworkable electronic apparatus according to another embodiment of the invention. The reworkable electronic apparatus 200 can be a mobile device, such as a tablet computer or a smart phone. The first component 110 can be a display module 210. The second component 120 can be a frame 220. The display module 210 can be a touch screen, which includes a touch panel 212 and a display panel 214. The display panel 214 is mounted on the touch panel 212. The reworkable electronic apparatus 200 includes an adhesive 230, and the adhesive 230 is disposed on the surface of the touch panel 212 corresponding to the frame 220. The adhesive 230 surrounds the display panel 214. Namely, the touch panel 212 includes a display area corresponding to the display panel 214, and a backing adhesive area surrounding the display area. The adhesive 230 is disposed at the backing adhesive area. The reworkable electronic apparatus 200 includes a plurality of shape memory metal pieces 240. The shape memory metal pieces 240 are disposed on the frame 220. The frame 220 can include a plurality of cavities 222 facing the backing adhesive area for receiving the shape memory metal pieces 240. The adhesive 230 may adhere display module 210 to the frame 220.

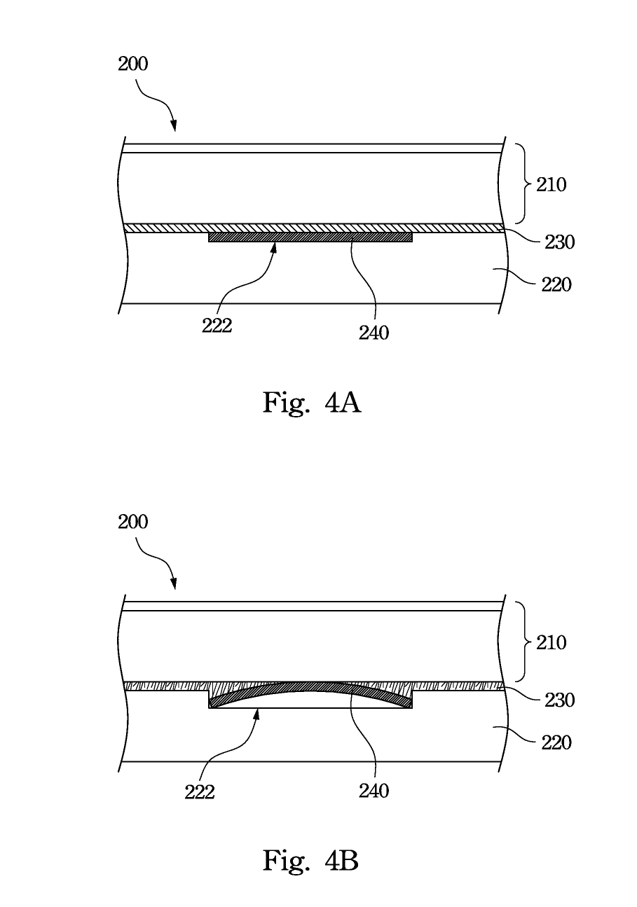

FIG. 4A is a schematic partial diagram of the reworkable electronic apparatus of FIG. 3 before being heated, and FIG. 4B is a schematic partial diagram of the reworkable electronic apparatus of FIG. 3 after being heated. In FIG. 4A, the shape memory metal piece 240 located in the cavity 222 is a flat sheet with a flat surface under a room temperature. The display module 210 can be fastened on the frame 220 with the adhesive 230. However, when the shape memory metal piece 240 is heated up to a predetermined temperature, such as 60° C., the shape memory metal piece 240 is deformed and bended, as shown in FIG. 4B. Furthermore, heating the reworkable electronic apparatus 200 may also reduce the adhesiveness of the adhesive 230. Therefore, the display module 210 can be easily lifted away from the frame 220 because of the deformation of the shape memory metal piece 240 and the adhesiveness reduction of the adhesive 230, thereby preventing the glass substrate of the display module 210 from being damaged during disassembling the reworkable electronic apparatus 200. The deformed shape of the shape memory metal piece 240 can be shown as FIG. 4B, in which the shape memory metal piece 240 is protruded toward the display module 210 after being heated. In other embodiments, the shape memory metal piece 240 is protruded toward the frame 220 after being heated.

When the reworkable electronic apparatus is heated to a predetermined temperature, the shape memory metal piece between the first component and the second component is deformed for providing a lifting force. Furthermore, the adhesiveness of the adhesive is reduced because of the raising temperature. Thus, the first component can be easily lifted away from the second component during a rework process thereby reducing the damage due to forcing disassembly.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A reworkable electronic apparatus, comprising:
a display module, comprising:
a display panel, comprising:
a display area; and
a backing adhesive area surrounding the display area; and
a touch panel placed on the display panel;
a frame;
to an adhesive disposed on the backing adhesive area for adhering the display module to the frame; and
at least one shape memory metal piece disposed between the display module and the frame, wherein the shape memory metal piece is deformable by heat for lifting the display module away from the frame.

2. The reworkable electronic apparatus of claim 1, wherein the shape memory metal piece has a flat surface at a room temperature.

3. The reworkable electronic apparatus of claim 1, wherein the shape memory metal piece is protruded toward the display module after being heated.

4. The reworkable electronic apparatus of claim 1, wherein the shape memory metal piece is protruded toward the frame after being heated.

5. The reworkable electronic apparatus of claim 1, wherein the frame comprises a cavity facing the backing adhesive area for receiving the shape memory metal piece.

6. A thermal disassembling method for a reworkable electronic apparatus, the method comprising:
providing the reworkable electronic apparatus of claim 1; and
heating the reworkable electronic apparatus for deforming the shape memory metal piece, thereby lifting the display module away from the frame.

7. The thermal disassembling method of claim 6, wherein the shape memory metal piece is protruded toward the display module after being heated.

8. The thermal disassembling method of claim 6, wherein the shape memory metal piece is protruded toward the frame after being heated.

9. The reworkable electronic apparatus of claim 6, wherein the frame comprises a cavity facing the backing adhesive area for receiving the shape memory metal piece.
